(19) United States
(12) Patent Application Publication
(10) Pub. No.: US 2005/0212530 A1
(43) Pub. Date: Sep. 29, 2005

(54) Method and Apparatus for Testing Electromagnetic Connectivity in a Drill String

(76) Inventors: David R. Hall, Provo, UT (US); H. Tracy Hall JR., Provo, UT (US); David S. Pixton, Lehi, UT (US); Michael Rawle, Springville, UT (US); David B. Bartholomew, Springville, UT (US); Marshall A. Soares, Taylorsville, UT (US)

Correspondence Address: JEFFREY E. DALY;GRANT PRIDECO, L.P., 400 N. SAM HOUSTON PARKWAY EAST, SUITE 900, HOUSTON, TX, 77060, US

(21) Appl. No.: 10/708,775

(22) Filed: Mar. 24, 2004

(51) Int. Cl. G01R 27/04

(52) U.S. Cl. 324/642

(57) ABSTRACT

A method and apparatus for testing electromagnetic connectivity in a drill string are disclosed. The method includes transmitting a test signal down a transmission path in a drill string; receiving a reflection of the test signal; and determining from the reflection whether there is an interruption in the electromagnetic connectivity in the transmission path. In general, the apparatus includes a signal generator for generating a test signal into the drill string; a receiver for receiving the reflection of the test signal; and means for determining from the reflection whether there is an interruption in the electromagnetic connectivity in the transmission path. Preferably, a common coil is included through which the test signal generated by the signal generator may be transmitted into a drill string and through which a reflection of the test signal may be received.

### FEDERAL RESEARCH STATEMENT

This invention was made with government support under Contract No. DE-FC26-97FT343656 awarded by the U.S. Department of Energy. The government has certain rights in the invention.

### BACKGROUND OF INVENTION

1. Field of the Invention

The present invention pertains to drill strings, and, more particularly, to a method and apparatus for testing electromagnetic connectivity in a drill string.

2. Description of the Related Art

Drilling operations, especially to establish production of hydrocarbon deposits, frequently employ relatively long drill strings terminated by a bit. The drill string is usually fed through the floor of a drilling rig. As the bit bores through the earth, additional sections of drill pipe, tools, etc. are made up and become a portion of the drill string. The drill string may eventually reach as long as 20,000″ 30,000″, or even longer.

As the industry evolves, obtaining information downhole regarding the drilling conditions is becoming more important. Some drilling applications also seek to control the direction of drilling from the surface by sending control signals downhole to the bit. The industry is therefore using a lot of instrumented tools and bits in drill strings. This requires electromagnetic connectivity up and down the drill string to provide power, transmit control information, and receive data.

Interruptions in this electromagnetic connectivity create numerous problems. The most immediate problem is the inability to send and receive signals to downhole, instrumented tools and bits. However, this problem leads to another significant problem namely, whether to proceed with drilling or to correct the connectivity problem. Fixing the connectivity problem typically involves tripping the drill string out of the bore, i.e., withdrawing the drill string one section at a time, and dissembling each section from the string. For relatively long drill strings, this may be a time-consuming practice costing significant amounts of money. Furthermore, if the interruption is toward the top of the drill string, it may be much more desirable to correct right away than it would be if the interruption were at the bottom of the drill string. Thus, it would be useful to know where in the drill string the interruption occurs. Knowing the location of the interruption would also be useful to expedite tripping the drill string out of the whole.

### SUMMARY OF INVENTION

The invention is a method and apparatus for testing electromagnetic connectivity in a drill string. The method comprises transmitting a test signal down a transmission path in a drill string; receiving a reflection of the test signal; and determining from the reflection whether there is an interruption in the electromagnetic connectivity in the transmission path. In general, the apparatus comprises a signal generator for generating a test signal into the drill string; a receiver for receiving the reflection of the test signal; and means for determining from the reflection whether there is an interruption in the electromagnetic connectivity in the transmission path. Preferably, a common coil is included through which the test signal generated by the signal generator may be transmitted into a drill string and through which a reflection of the test signal may be received.

### BRIEF DESCRIPTION OF DRAWINGS

The invention may be understood by reference to the following description taken in conjunction with the accompanying drawings, in which like reference numerals identify like elements.

FIG. 1 illustrates an apparatus with which the method of the invention may be implemented in a first embodiment of the present invention.

FIG. 2 illustrates one particular embodiment of a method in accordance with the present invention.

FIG. 3A FIG. 3B depict an exemplary joint in the drill string of FIG. 1.

FIG. 4A FIG. 4C illustrate one section of pipe, two of which are mated to form the joint of FIG. 3A FIG. 3B.

FIG. 5A FIG. 5B illustrate an electromagnetic coupler of the section in FIG. 4A FIG. 4C in assembled and exploded views, respectively, that form a electromagnetic coupling in the joint of FIG. 3A FIG. 3B.

FIG. 6 conceptually illustrates a first embodiment of a testing apparatus of FIG. 1;

FIG. 7 graphs traces representative of reflected signals indicating a good connection and a bad connection, the bad connections arising from a shorted box end, an open box end, a shorted pin end, and an open pen end.

FIG. 8 conceptually illustrates a second embodiment of the testing apparatus of FIG. 1.

FIG. 9 conceptually illustrates a drilling operation employing the invention to test electromagnetic connectivity downhole in accordance with a second embodiment of the present invention alternative to that shown in FIG. 1.

FIG. 10 is a profile view illustrating a down-hole network implemented in the drilling operation of FIG. 9.

FIG. 11 is a schematic block diagram illustrating a high-level functionality of one embodiment of the down-hole network of FIG. 10.

FIG. 12 is a schematic block diagram illustrating one embodiment of a node used to implement the down-hole network of FIG. 10, including various devices, sensors, and tools in accordance with one particular embodiment of the present invention.

FIG. 13 is a schematic block diagram illustrating certain relationships among various hardware and corresponding functions provided by a node such as the node in FIG. 12.

FIG. 14 is a schematic block diagram illustrating one embodiment of a packet used to transmit data between nodes.

While the invention is susceptible to various modifications and alternative forms, the drawings illustrate specific embodiments herein described in detail by way of example. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers″ specific goals, such as compliance with system-related and business-related constraints, which will vary from one implementation to another. Moreover, it will be appreciated that such a development effort, even if complex and time-consuming, would be a routine undertaking for those of ordinary skill in the art having the benefit of this disclosure.

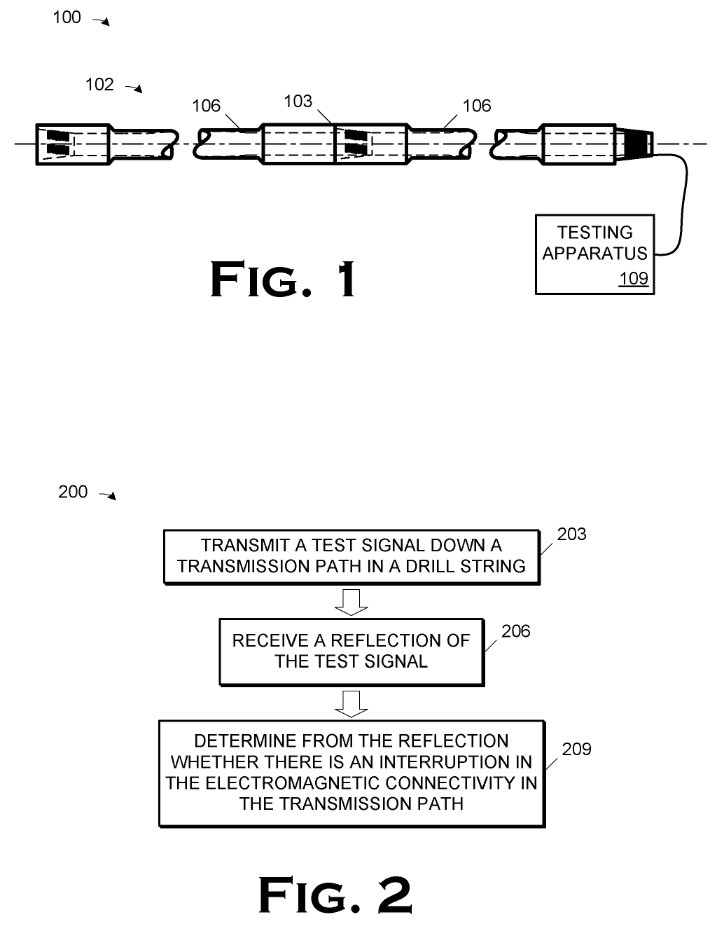

FIG. 1 illustrates an apparatus 100 with which the method of the invention may be implemented in a first embodiment. The apparatus 100 comprises a drill string 102 and a testing apparatus 109. The drill string includes a joint 103 comprised of two, mated sections 106 of drill pipe. Note that the number of sections 106 is not pertinent to the practice of the invention, although it may be a design consideration in some implementations. In some embodiments, the sections 106 may alternatively be tools (instrumented or not), crossovers, subs, etc. (all not shown) such as are commonly found in drill strings, or some combination of the above. In the illustrated embodiment, the joint 103 is made up in a rack (not shown) on the floor of the drilling rig before assembly into the drill string (not otherwise shown).

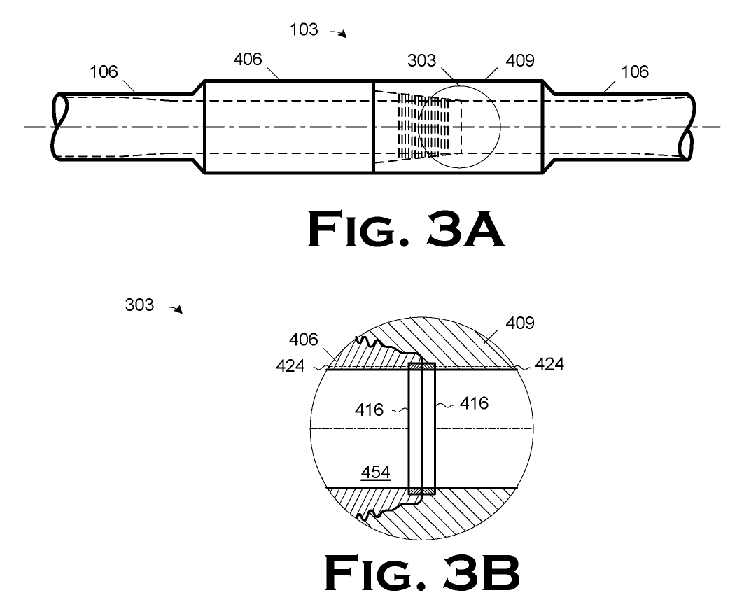

The drill string 102 comprises “wired pipe” that is, it includes a transmission path (not shown, but discussed further below) down its length. In accordance with the present invention, the electromagnetic conductivity along this transmission path is tested using, in this particular embodiment, the method 200 illustrated in FIG. 2. The method 200 begins by transmitting (at 203) a test signal down the transmission path in the drill string 102. The method 200 continues by receiving (at 206) a reflection of the test signal. A determination is then made (at 209) from the reflection whether there is an interruption in the electromagnetic connectivity in the transmission path. In the embodiment of FIG. 1, the testing apparatus 109 performs all these steps, but this functionality need not be centralized in a single apparatus in all embodiments.

The present invention contemplates wide variation in the implementation of the transmission path under test. However, the transmission path of the illustrated embodiment, and reasonable variations thereon, are more fully disclosed and claimed as follows:
U.S. Ser. No. 09/909,469, entitled “Downhole Data Transmission System for a String of Downhole Components,” and filed Jul. 18, 2001, in the name of the inventors David R. Hall, et al.
U.S. Ser. No. 10/358,099, entitled “Data Transmission System for a Downhole Component,” and filed Feb. 2, 2003, in the name of the inventors David R. Hall, et al.
U.S. Pat. No. 6,670,880, entitled “Downhole Data Transmission System,” and issued Dec. 30, 2003, in the name of the inventors David R. Hall, et al.

A fuller description of the drill string 102 excerpted from these references will now follow to provide a firmer understanding of the transmission path under test in the illustrated embodiment.

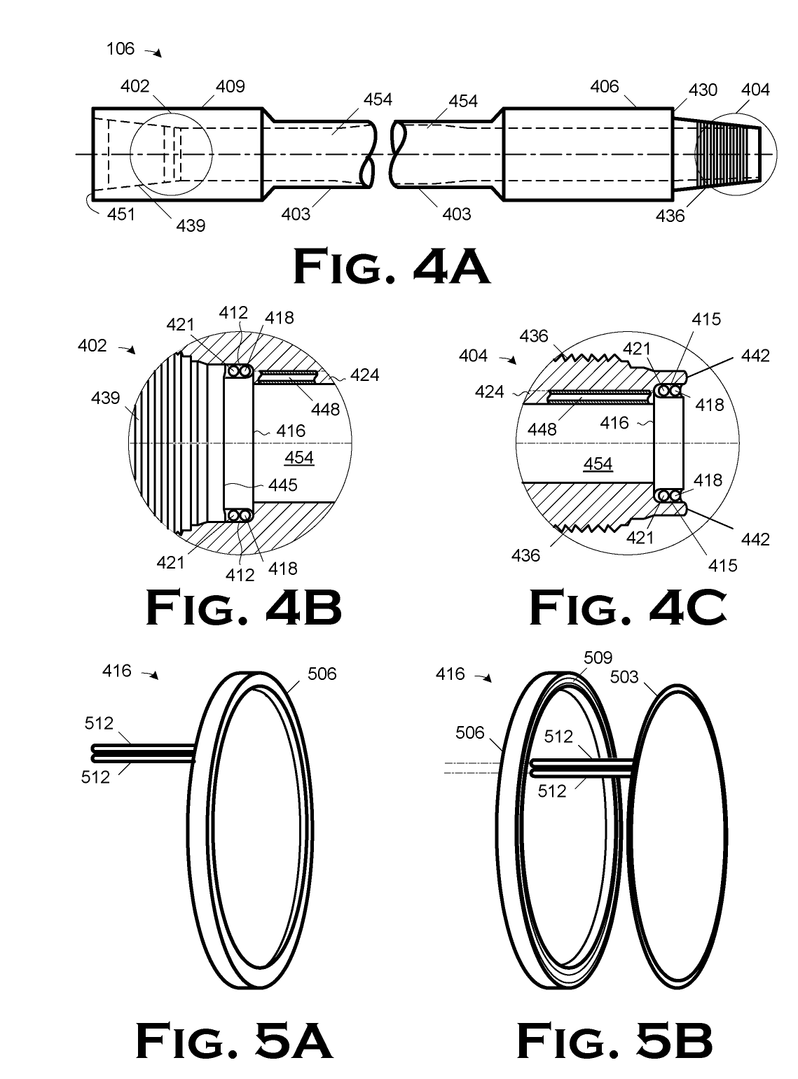

FIG. 3A is an enlarged view of the made up joint 103 of FIG. 1. The two individual sections 106 are best shown in FIG. 4A FIG. 4C. FIG. 3B is an enlarged view of a portion 303 of view in FIG. 3A of the joint 103. FIG. 4B FIG. 4C are enlarged views of a portion 402 of a box end 409 and a portion 404 of the pin end 406 of the section 106 as shown in FIG. 4A As will be discussed further below, each section 106 includes a transmission path that, when the two sections 106 are mated as shown in FIG. 3A, aligns. When energized, the two transmission paths electromagnetically couple across the joint 103 to create a single transmission path through the drill string 102. The present invention is directed to testing the electromagnetic connectivity across joints in a drill string such as the joint 103 and, hence, the transmission path in the drill string 102. Various aspects of the particular transmission path of the illustrated embodiment are more particularly disclosed and claimed in the aforementioned U.S. Pat. No. 6,670,880. Pertinent portions of that patent are excerpted below. However, the present invention may be employed with other types of drill pipe and transmission systems.

Turning now to FIG. 4A, each section 106 includes a tube body 403 welded to an externally threaded pin end 406 and an internally threaded box end 409. Pin and box end designs for sections of drill pipe are well known to the art, and any suitable design may be used. Acceptable designs include those disclosed and claimed as follows:
U.S. Pat. No. 5,908,212, entitled “Ultra High Torque Double Shoulder Tool Joint”, and issued Jun. 1, 1999, to Grant Prideco, Inc. of The Woodlands, Tex., as assignee of the inventors Smith, et al.
U.S. Pat. No. 5,454,605, entitled “Tool Joint Connection with Interlocking Wedge Threads”, and issued Oct. 3, 1995, to Hydril Company of Houston, Tex., as assignee of the inventor Keith C. Mott.

However, other pin and box end designs may be employed.

Grooves 412, 415, best shown in FIG. 4B FIG. 4C, are provided in the respective tool joint 103 as a means for housing electromagnetic couplers 416, each comprising one or more toroidal cores 418, 421 having magnetic permeability about which a radial or Archimedean coil (not shown) is wound. The groove 415 is recessed into the secondary shoulder, or face, 442 of the pin end 406. The groove 412 is recessed into the internal shoulder 445. Additional information regarding the pin and box ends 406, 409, their manufacture, and placement is disclosed in:
The aforementioned U.S. Pat. No. 6,670,880.
U.S. application Ser. No. 10/605,484, entitled “Tool Joints Adapted for Electrical Transmission,” and filed Oct. 2, 2003, in the name of David R. Hall, et al.

In the illustrated embodiment, the grooves 415, 412 are located so as to lie equidistant between the inner and outer diameter of the face 442 and the shoulder 445. Further, in this orientation, the grooves 415, 412 are located so as to be substantially aligned as the joint 103 is made up.

FIG. 5A-FIG. 5B illustrate an electromagnetic coupler 416 in assembled and exploded views, respectively. Additional information regarding the construction and operation of the electromagnetic coupler 416 in various alternative embodiments are disclosed in: the aforementioned U.S. Pat. No. 6,670,880.
U.S. application Ser. No. 10/430,734, entitled “Loaded Transducer for Downhole Drilling components,” and filed May 6, 2003, in the name of David R. Hall, et al.
U.S. application Ser. No. 10/612,255, entitled “Improved Transmission Element for Downhole Drilling Components,” and filed Jul. 2, 2003, in the name of David R. Hall, et al.
U.S. application Ser. No. 10/653,564, entitled “Polished Downhole Transducer Having Improved Signal Coupling” and filed Sep. 2, 2003, in the name of David R. Hall, et al.
U.S. application Ser. No. 10/605,493, entitled “Improved Electrical Contact For Downhole Drilling Networks” and filed Oct. 2, 2003, in the name of David R. Hall, et al.

Parts of these references are excerpted below with respect to this particular embodiment of the electromagnetic couplers 416.

As previously mentioned, the electromagnetic coupler 416 consists of an Archimedean coil, or planar, radially wound, annular coil 503, inserted into a core 506. The laminated and tape wound, or solid, core 506 may be a metal or metal tape material having magnetic permeability, such as ferromagnetic materials, irons, powdered irons, ferrites, or composite ceramics, or a combination thereof. In some embodiments, the core material may even be a material without magnetic permeability such as a polymer, like polyvinyl chloride (“PVC”). More particularly, in the illustrated embodiment, the core 506 comprises a magnetically conducting, electrically insulating (“MCEI”) element. The annular coils 503 may also be wound axially within the core material and may consist of one or more than one layers of coils 503.

As can best be seen in the cross section in FIG. 5B, the core 506 includes a U-shaped trough 509. The dimensions of the core 506 and the trough 509 can be varied based on the following factors. First, the 506 must be sized to fit within the grooves 412, 415. In addition, the height and width of the trough 509 should be selected to optimize the magnetically conducting properties of the core 506. Lying within the trough 509 of the core 506 is an electrically conductive coil 503. This coil 503 comprises at least one loop of an insulated wire (not otherwise shown), typically only a single loop. The wire may be copper and insulated with varnish, enamel, or a polymer. A tough, flexible polymer such as high density polyethylene or polymerized tetrafluoroethane (“PTFE”) is particularly suitable for an insulator. The specific properties of the wire and the number of loops strongly influence the impedance of the coil 503.

The coil 503 is preferably embedded within a material (not shown) filling the trough 509 of the core 506. The material should be electrically insulating and resilient, the resilience adding further toughness to the core 506. Standard commercial grade epoxies combined with a ceramic filler material, such as aluminum oxide, in proportions of about 50/50 percent suffice. The core 506 is, in turn, embedding in a material (not shown) filling the groove 412 or 415. This second embedment material holds the core 506 in place and forms a transition layer between the core 506 and the steel of the pipe to protect the core 506 from some of the forces seen by the steel during joint makeup and drilling. This resilient, embedment material may be a flexible polymer, such as a two-part, heat-curable, aircraft grade urethane. Voids or air pockets should also be avoided in this second embedment material, e.g., by centrifuging at between 2500 to 5000 rpm for about 0.5 to 3 minutes.

In one particular embodiment (not shown), the core 506 is comprised of a plurality of segmented ferrite elements are held together in the appropriate configuration by means of a resilient material, such as an epoxy, a natural rubber, a fiberglass or carbon fiber composite, or a polyurethane, that forms a base for the segmented ferrite elements. Examples of such an embodiment may be found in:
U.S. application Ser. No. 09/909,469, entitled “Data Transmission System for a String of Downhole Components,” filed Jul. 18, 2001, in the name of the inventors David R. Hall, et al.
U.S. application Ser. No. 10/430,734, entitled “Loaded Transducer for Downhole Drilling Components,” filed May 6, 2003, in the name of the inventors David R. Hall, et al.

However, such an embodiment for the core 506 is not necessary to the practice of the invention, and other suitable embodiments may be employed.

Returning to FIG. 4B FIG. 4C, a rounded groove 424 is formed within the bore wall for conveying an insulated conductor means 448 along the section 106. The conductor means 448 is attached within the groove 424 and shielded from the abrasive drilling fluid. The conductor means 448 may consist of wire strands or a coaxial cable. The conductor means 448 is mechanically attached to each of the toroidal cores 418, 421 in a manner not shown. When installed into the grooves 412, 415, the electromagnetic couplers 416 are potted in with an abrasion resistant material in order to protect them from drilling fluids (not shown).

An electrical conductor 448, shown in FIG. 4B FIG. 4C, is connected between the coils 503 at the box and pin ends 406, 409 of the section 106. The electrical conductor 448 is, in the illustrated embodiment, a coaxial cable with a characteristic impedance in the range of about 30 W-120 W, e.g., in the range of about 50 W-75 W. In the illustrated embodiment, the electrical conductor 503 has a diameter of about 0.25″ or larger. Various aspects of suitable coaxial cables and their retention in and connection to other elements of the transmission path in various alternative embodiments are disclosed in:
U.S. application Ser. No. 10/605,373, entitled “Load-Resistant Coaxial Transmission Line,” and filed Sep. 25, 2003, in the name of David R. Hall, et al.
U.S. application Ser. No. 10/456,104, entitled “Electrical Transmission Line Diametrical Retention Mechanism” and filed Jun. 9, 2003, in the name of David R. Hall, et al.
U.S. application Ser. No. 10/358,099, entitled “Data Transmission System for a Downhole Component” and filed Feb. 2, 2003, in the name of David R. Hall, et al.
U.S. application Ser. No. 10/212,187, entitled “An Expandable Metal Liner for Downhole Components,” and filed Aug. 5, 2002, in the name of David R. Hall, et al.
U.S. application Ser. No. 10/427,522, entitled “Data Transmission System for a Downhole Component,” and filed Apr. 30, 2003, in the name of David R. Hall, et al.
U.S. application Ser. No. 10/640,956, entitled “An Internal Coaxial Cable Seal System,” and filed Aug. 14, 2003, in the name of David R. Hall, et al.
U.S. application Ser. No. 10/605,863, entitled “Improved Drill String Transmission Line,” and filed Oct. 31, 2003, in the name of David R. Hall, et al.
U.S. application Ser. No. 10/653,604, entitled “Drilling Jar for Use in a Downhole Network,” and filed Sep. 2, 2003 in the name of David R. Hall, et al.
U.S. application Ser. No. 10/707,232, entitled “Seal for Coaxial Cable in Downhole Tools,” and filed Nov. 28, 2003, in the name of David R. Hall, et al.
U.S. application Ser. No. 10/707,673, entitled “Apparatus and Method for Bonding a Transmission Line to a Downhole Tool,” and filed Dec. 31, 2003, in the name of David R. Hall, et al.

However, other conductors (e.g., twisted wire pairs) may be employed in alternative embodiments.

The conductor loop represented by the coils 503 and the electrical conductor 448 is completely sealed and insulated from the pipe of the section 106. The shield (not otherwise shown) should provide close to 100% coverage, and the core insulation should be made of a fully-dense polymer having low dielectric loss, e.g., from the family of polytetrafluoroethylene (“PTFE”) resins, Dupont″s Teflon® being one example. The insulating material (not otherwise shown) surrounding the shield should have high temperature resistance, high resistance to brine and chemicals used in drilling muds. PTFE is again preferred, or a linear aromatic, semi-crystalline, polyetheretherketone thermoplastic polymer manufactured by Victrex PLC under the trademark PEEKÒ. The electrical conductor 448 is also coated with, for example, a polymeric material selected from the group consisting of natural or synthetic rubbers, epoxies, or urethanes, to provide additional protection for the electrical conductor 448.

Referring now to FIG. 4A and FIG. 5A, as was mentioned above, the coil 503 of the illustrated embodiment extends through the core 506 to meet the electrical conductor 448 at a point behind the core 506. Typically, the input leads 512 extend through not only the core 506, but also holes (not shown) drilled in the grooves 415, 412 through the enlarged walls of the pin end 406 and box end 409, respectively, so that the holes open into the central bore 454 of the pipe section 11. The diameter of the hole will be determined by the thickness available in the section 106 and the input leads 512. For reasons of structural integrity it is preferably less than about one half of the wall thickness, with the holes typically having a diameter of about between 3 mm and 7 mm. The input leads 512 may be sealed in the holes by, for example, urethane. The input leads 512 are soldered to the electrical conductor 448 to effect the electrical connection therebetween.

Returning to FIG. 3A, a pin end 406 of a first section 106 is shown mechanically attached to the box end 409 of a second section 106 by means of the mating threads 436, 439. The sections 106 are screwed together until the external shoulders 430, 451 are compressed together forming the primary seal for the joint 103 that prevents the loss of drilling fluid and bore pressure during drilling. When the joint 103 is made up, it is preloaded to approximately one half of the torsional yield strength of the pipe, itself. The preload is dependent on the wall thickness and diameter of the pipe, and may be as high as 70,000 foot-pounds. The grooves 412, 415 should have rounded corners to reduce stress concentrations in the wall of the pipe.

When the pin and box ends 406, 409 of two sections 106 are joined, the electromagnetic coupler 416 of the pin end 406 and the electromagnetic coupler 416 of the box end 409 are brought to at least close proximity. The coils 503 of the electromagnetic couplers 416, when energized, each produces a magnetic field that is focused toward the other due to the magnetic permeability of the core material. When the coils are in close proximity, they share their magnetic fields, resulting in electromagnetic coupling across the joint 103. Although is not necessary for the electromagnetic couplers 416 to contact each other for the coupling to occur, closer proximity yields a stronger coupling effect.

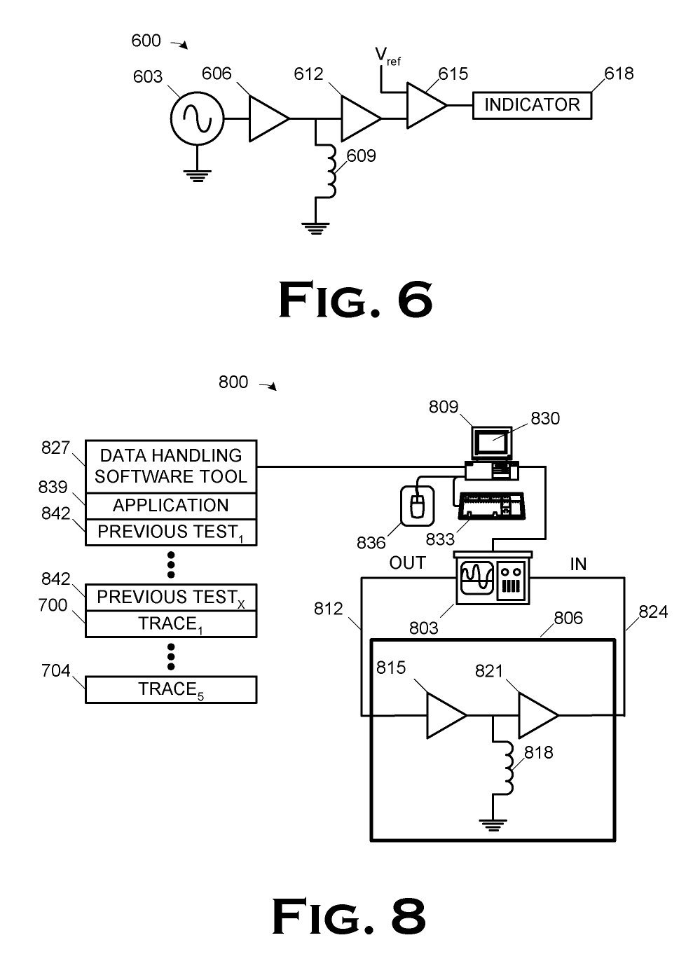

Returning now to FIG. 1, the testing apparatus 109 may be implemented in a variety of ways. A first embodiment 600 for the testing apparatus 109 is shown in FIG. 6. In the embodiment 600, a crystal-based oscillator 603 generates a test signal that is transmitted via the amplifier 606 and the coil 609 down the drill string 102, shown in FIG. 1. In the illustrated embodiment, the test signal is a basic 1 MHz-20 Mhz, 3.0 Vp-p-0.1 Vp-p sine wave signal, although alternative embodiments may employ alternative waveforms and/or signals with alternative characteristics. The coil 609 couples with the electromagnetic coupler 416 of one of the sections 106, preferably at the pin end 406 of the drill string 102, since it is easier to reach. Note, however, that alternative embodiments may couple the embodiment 600 through the coil 609 to the electromagnetic coupler 416 at the box end 409 of the drill string 102.

As those in the art having the benefit of this disclosure will appreciate, the test signal will be reflected by the termination of the transmission path over which it travels. The reflection is received via the coil 609 and the amplifier 612 and compared to a reference signal Vref by the amplifier 615. Depending on the output of the amplifier 615, the indicator 618 provides an indication of whether the electromagnetic connection across the joint 103, shown in FIG. 1 is good. The indication may be visual. For example, the indicator 618 may be a light emitting diode that lights up to indicate that a good connection has been made. The indication may be auditory, or aural. For example, a small chime or buzzer may be set off when a good connection is detected. Or, some combination of these two may be employed. Other alternatives will become apparent to those skilled in the art having the benefit of this disclosure.

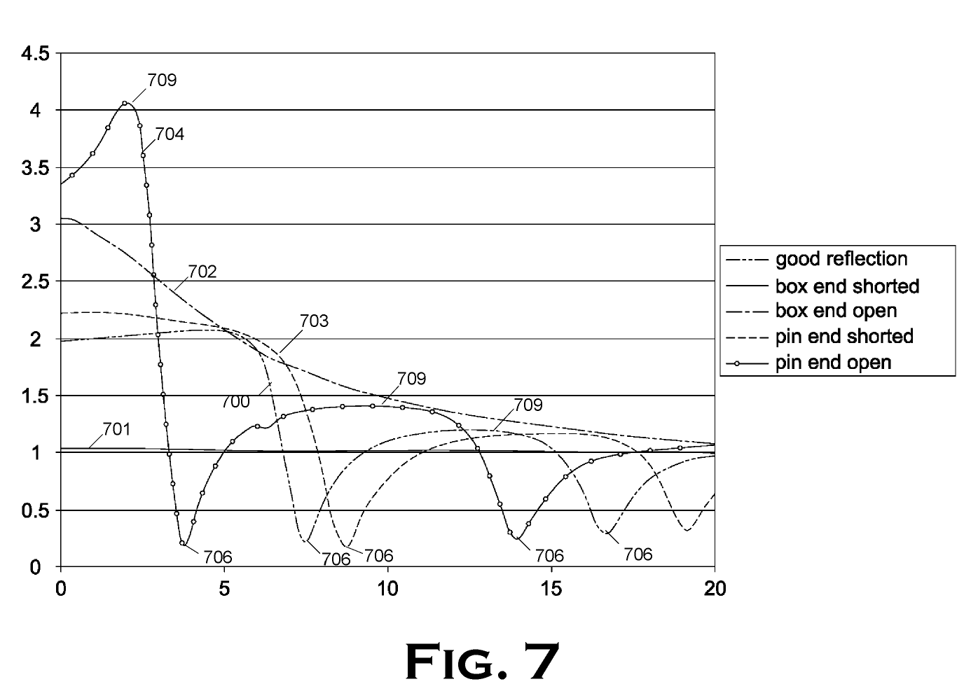

FIG. 7 graphs a variety of signals to illustrate how comparison can indicate whether a good connection has been made. The trace 700 is of a reflected signal indicating that a good connection has been made. Thus, the trace 700 can be, in the embodiment of FIG. 6, the reference signal Vref. FIG. 7 also includes a plurality of traces 701 704 representing reflections from a shorted box end, an open box end, a shorted pin end, and an open pen end, respectively. Each of the traces 700 704 represents the amplitude (in volts) of the reflected signal over time. Note that each condition generates a unique pattern in the reflection. Thus, a more sophisticated examination of the reflected signal than is performed in the embodiment 600 in FIG. 6 can reveal not only that a connection is bad, but also the nature of the bad connection.

Consider the embodiment 800, shown in FIG. 8, of the testing apparatus 109, first shown in FIG. 1. The embodiment 800 comprises a network analyzer 803, a test fixture 806, and a computing apparatus 809. The network analyzer 803 generates the test signal (not shown) and outputs it on the line 812. The test signal is transmitted by the test fixture 803 to the drill string 103 through the amplifier 815 and the coil 818, which is coupled to the drill sting 103 through its electromagnetic coupler 416, as described above for the embodiment 600 of FIG. 6. The test fixture 803 receives the reflection from the drill string 102 through the coil 818 and outputs it to the network analyzer 803 through the amplifier 821 over the line 824.

The network analyzer 803, in turn, outputs the received reflected signal to the computing apparatus 809 over the line 827. The computing apparatus 809 is programmed with and executing a data handling software tool 827, such as one of the many commercially available from LABVIEWÒ. The data handling software tool 827 may be, for instance, encoded on the random access storage (not shown) of the computing apparatus 809 and executed by the processor (also not shown) thereof. The data handling software tool 827 collects and displays the data representing the reflected signal along with a reference standard. For instance, the data handling software tool 827 may display the trace 700 as the reference representing a good connection and a trace representing the reflected signal on the display 830 of the computing apparatus 809. A user may then visually inspect the two traces to determine whether a good connection has been made.

The invention contemplates variation in this aspect of the invention. For instance, in some embodiments, a user may use peripheral devices, such as the keyboard 833 and the mouse 836, to interact with the data handling software tool 827 through a graphical user interface (“GUI”, not shown). Such interaction may be to impose one or more of the exemplary traces 700 704 to assist in the evaluation, or to manipulate the display in some fashion. In these embodiments, the traces 700 704 may be stored in the storage of the computing apparatus 809, as shown in FIG. 8. Some embodiments might even store the traces 700 704 or the results 842 of previous joint tests that can be retrieved by the user in this fashion to compare with the current reflected signal. The traces or the results 842 of previous tests can also be categorized in these embodiments. For example, some of the traces or the results 842 may be stored in a first data structure (not shown) for good connections while the rest of the traces or the results 842 may be stored in a second data structure (also not shown) for bad connections. Alternatively, the traces or the results 842 from previous tests that are from bad connections can be categorized by their cause, e.g., a shorted box end, an open box end, a shorted pin end, or an open pen end.

Returning to FIG. 1, as was mentioned above, one or more of the sections 106 may be a tool, such as an instrumented tool for measuring drilling conditions downhole. See, e.g., U.S. application Ser. No. 10/250,245, entitled “Method and Apparatus for Transmitting and Receiving Data to and From a Downhole Tool (Adapter)”, and filed Jun. 17, 2003, in the name of the inventors David R. Hall, et al., for an example of how the above transmission path can be employed in instrumented tools. Active instruments or other active components on the transmission path can interfere with obtaining a reflection from which an accurate determination of the electromagnetic conductivity can be made. Thus, the transmission path under test can be routed so that the instruments are not on the transmission path under test. Or, the instruments can be turned off for the time during which the electromagnetic connectivity of the drill string 102 is under test. Still other techniques may be employed to mitigate or excise the adverse effects of active components on the transmission path under test during the test.

Also as was earlier noted, there is no theoretical limitation on the length of the drill string 102 and, hence, the transmission path. However, there may be practical limitations various alternative embodiments. Referring now again to FIG. 7, the traces 700 701 represent reflections in a drill string 102 comprising only a single joint 103. Each of the traces 700 701 includes a characteristic series of nulls 706 and peaks 709 (not all indicated). Each joint 103 introduces a phase shift in the reflection that will shift the location of these nulls 706 and peaks 709 within the given shift. Although the pattern of the nulls 706 and peaks 709 will remain repeatable and distinctive, the waveform becomes more complex, and therefore more difficult to analyze as additional sections 106 are added to the drill string 102. Thus, increasing the length of the drill string 102, shown in FIG. 1, increases the complexity of determining (at 209, FIG. 2) whether the connection is good or bad. Some embodiments may therefore seek to limit the length of the drill string 102 under test.

The present invention also is not limited to applications in which the drill string 102 is assembled and tested on the floor of the drilling rig. For instance, the present invention may be used in quality assurance testing after the sections 102 are manufactured but before they are shipped to a customer. Use of the invention in this fashion can, for example, test the transmission path to see if various portions, e.g., the electromagnetic couplers 416, shown best in FIG. 5A FIG. 5B, were damaged during assembly of the section 106. Other applications of the invention in this context may also become apparent to those of ordinary skill in the art having the benefit of this disclosure.

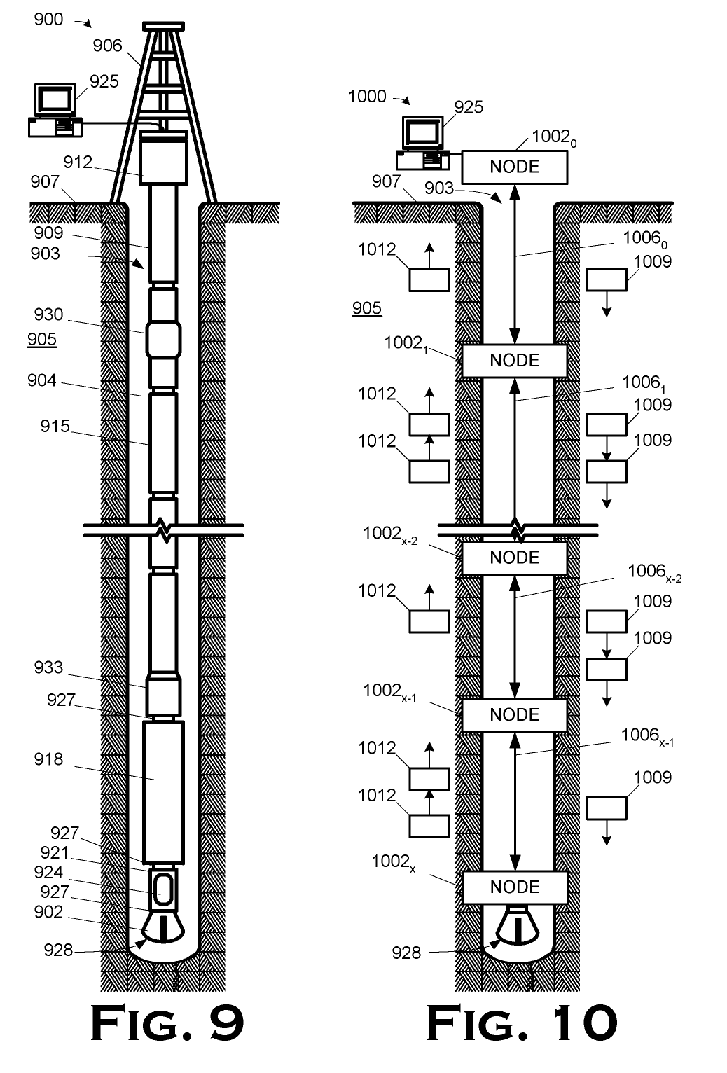

The present invention can also be used to test electromagnetic connectivity in a drill string downhole. FIG. 9 schematically illustrates a drilling operation 900 in which a drill string 903, including a bit 902, is drilling a borehole 904 in the ground 905 beneath the surface 907 thereof. In this particular embodiment, the drill string 903 implements a “downhole local area network,” or “DLAN” more fully disclosed and claimed in U.S. Provisional Patent Application No. 60/481,225, entitled “Downhole Network,” and filed Aug. 13, 2003, in the name of David R. Hall, et al. In the interest of clarity, some portions of that reference will be excerpted below.

The drilling operation 900 includes a rig 906 from which the drill string 903 is suspended through a kelly 909. A data transceiver 912 is fitted on top of the kelly 909, which is, in turn, connected to a drill string 903 comprised of a plurality of sections of drill pipe 915 (only one indicated). Also within the drill string 903 are tools (not indicated) such as jars and stabilizers. Drill collars (also not indicated) and heavyweight drill pipe 918 are located near the bottom of the drill string 903. A data and crossover sub 921 is included just above the bit 902. The drill string 903 interfaces with a computing apparatus 925 through the kelly 909 by means of a swivel, such as is known in the art. One particular implementation employs a swivel disclosed more fully in U.S. application Ser. No. 10/315,263, entitled “Signal Connection for a Downhole Tool String”, and filed Dec. 10, 2002, in the name of the inventors David R. Hall, et al.

The drill string 903 will include a variety of instrumented tools for gathering information regarding downhole drilling conditions. For instance, the bit 902 is connected to a data and crossover sub 921 housing a sensor apparatus 924 including an accelerometer (not otherwise shown). The accelerometer is useful for gathering real time data from the bottom of the hole. For example, the accelerometer can give a quantitative measure of bit vibration. The data and crossover sub 921 includes a transmission path such as that described above for the sections 106 in FIG. 4A FIG. 4C. So, too do the bit 902 and the heavyweight drill pipe 918. The bit 902, data and crossover sub 921, and sensor apparatus 924 generally comprise, in part, a bottom-hole assembly 928, although the constitution of the bottom-hole assembly 928 is not material to the practice of the invention.

The joints 927 between these sections of the drill string 903, as well as the other joints (not indicated) of the drill string 903 comprise joints such as the joint 103 best shown in FIG. 3A FIG. 3B. Many other types of data sources may and typically will be included. Exemplary measurements that may be of interest include hole temperature and pressure, salinity and pH of the drilling mud, magnetic declination and horizontal declination of the bottom-hole assembly, seismic look-ahead information about the surrounding formation, electrical resistivity of the formation, pore pressure of the formation, gamma ray characterization of the formation, and so forth.

To accommodate the transmission of the anticipated volume of data, the drill string 903 will transmit data at a rate of at least 100 bits/second, and on up to at least 1,000,000 bits/second. However, signal attenuation is a concern. A typical length for a section of pipe (e.g., the section 106 in FIG. 4A), is 30″ 90″. Drill strings in oil and gas production can extend as long as 20,000″ 30,000″, or longer, which means that as many as 700 sections of drill pipe, down hole tools, collars, subs, etc. can found in a drill string such as the drill string 1203. The transmission line created through the drill string by the pipe described above will typically transmit the information signal a distance of 1,000 to 2,000 feet before the signal is attenuated to the point where amplification will be desirable. Thus, amplifiers, or “repeaters,” 930 (only one shown) are provided for approximately for some of the components in the drill string 1203, for example, 5% of components not to exceed 10%, in the illustrated embodiment.

Such repeaters can be simple “dumb” repeaters that only increase the amplitude of the signal without any other modification. A simple amplifier, however, will also amplify any noise in the signal. Although the down-hole environment may be relatively free of electrical noise in the RF frequency range preferred by the illustrated embodiment, a “smart” repeater that detects any errors in the data stream and restores the signal, error free, while eliminating baseline noise, is preferred. Any of a number of known digital error correction schemes can be employed in a down-hole network incorporating a “smart” repeater. One suitable smart repeater is disclosed in U.S. application Ser. No. 10/613,549, entitled “Link Module For a Downhole Drilling Network,” and filed Jul. 1, 2003, in the name of David R. Hall, et al.

As is the case with the repeaters 930, the drill string 903 also includes a number of testing apparatuses, such as the testing apparatus 933. Each testing apparatus 933 may comprise a dedicated section of the drill string 903, as is the case for the embodiment illustrated in FIG. 9. Alternatively, the testing apparatrus 933 may be hosted on other sections of the drill string 903. For instance, a repeater 930 may also host a testing apparatus 933 such that there is no section of the drill string 903 dedicated to hosting the testing apparatus 933. However, in the illustrated embodiment, the testing apparatus 933 comprises a dedicated section of the drill string 903.

Each of the testing apparatuses 933 generates a test signal, transmits it across a predetermined number of joints 927 further down in the drill string 903, and receive the reflections thereof. The testing apparatuses 933 then transmit the reflections, or data representing the reflections, back uphole to the computing apparatus 925. The computing apparatus 925 is programmed with respect to the invention in a manner similar to the computing apparatus 809 in FIG. 8. (Note that the computing apparatus 925 is also programmed as a part of the DLAN discussed above.) The data can then be displayed by the computing apparatus 925 and the user can interact therewith in the same manner as described relative to the testing apparatus 800 of FIG. 8.

Thus, the computing apparatus 925 is programmed to facilitate determining from the reflection whether there is an interruption in the electromagnetic connectivity in the transmission path. Note, however, that the computing apparatus 925 may make the determination itself; for example, in a manner analogous to the embodiment 500 in FIG. 5A. Note also that distributing the testing apparatuses 933 throughout the drill string 903 simplifies the traces from which the determination of connectivity is made and facilitates a finer granularity in the locating a bad connection, should one exist.

Note that some portions of the detailed descriptions herein are consequently presented in terms of a software implemented process involving symbolic representations of operations on data bits within a memory in a computing system or a computing device. These descriptions and representations are the means used by those in the art to most effectively convey the substance of their work to others skilled in the art. The process and operation require physical manipulations of physical quantities. Usually, though not necessarily, these quantities take the form of electrical, magnetic, or optical signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantifies. Unless specifically stated or otherwise as may be apparent, throughout the present disclosure, these descriptions refer to the action and processes of an electronic device, that manipulates and transforms data represented as physical (electronic, magnetic, or optical) quantities within some electronic device″s storage into other data similarly represented as physical quantities within the storage, or in transmission or display devices. Exemplary of the terms denoting such a description are, without limitation, the terms “processing,” “computing,” “calculating,” “determining,” “displaying,” and the like.

Note also that the software implemented aspects of the invention are typically encoded on some form of program storage medium or implemented over some type of transmission medium. The program storage medium may be magnetic (e.g., a floppy disk or a hard drive) or optical (e.g., a compact disk read only memory, or “CD ROM”), and may be read only or random access. Similarly, the transmission medium may be twisted wire pairs, coaxial cable, optical fiber, or some other suitable transmission medium known to the art. The invention is not limited by these aspects of any given implementation.

In one embodiment, shown in FIG. 10, the drill string 903 implements a down-hole network 1000, which includes a plurality of nodes 1002 (i.e., the nodes 10020 1002x) used to transmit information along the drill string 903. Note that the number of nodes 1002 is not material to the practice of the invention and will be an implementation specific detail. The nodes 1002 in the illustrated embodiment also implement the signal repeaters 930, and so are spaced every 1,000″ or so. Thus, in the illustrated embodiment, the number of nodes 1002 is a function of the overall length of the drill string 903. The nodes 1002 may be intelligent computing devices, or may be less intelligent connection devices, such as hubs or switches located along the length of the network 1000. Each of the nodes 1002 may or may not be addressed on the network 1000.

The bottom-hole node 1002x interfaces with the bottom-hole assembly 928 located at the end of the drill string 903. Other, intermediate, nodes 10021-1002x-1 may be located or spaced to act as relay points for signals traveling along the down-hole network 1000 and to interface with various tools or sensors (not shown in FIG. 10) located along the length of the drill string 903. Likewise, the top-hole node 10020 may be located at the top or proximate the top of a drill string 903 to interface with a computing apparatus 925 with which the data collected can be captured, stored, and/or analyzed.

Communication links 10060 1006x-1 may be used to connect the nodes 10020 1002x to one another. The communication links 10060 1006x-1 may be comprised of cables or other transmission media integrated directly into sections 106 of the drill string 903, routed through the central bore of a drill string, or routed externally to the drill string. Likewise, in certain contemplated embodiments in accordance with the invention, the communication links 10060 1006x-1 may be wireless connections. In certain embodiments, the down-hole network 1000 may function as a packet-switched or circuit-switched network 1000.

As in most networks, a plurality of packets 1009, 1012 are used to transmit information among the nodes 10020 1002x. The packets 1012 may be used to carry data from tools or sensors, located down-hole, to an up-hole node 10020, or may carry protocols or data necessary to the functioning of the network 1000. Likewise, selected packets 1009 may be transmitted from up-hole nodes 10020 to down-hole nodes 10021-1002x. These packets 1009, for example, may be used to send control signals from a top-hole node 1002x to tools or sensors located proximate various down-hole nodes 10021-1002x. Thus, a down-hole network 1000 may provide an effective means for transmitting data and information between components located down-hole on a drill string 903, and devices located at or near the surface of the earth 102.

To accommodate the transmission of the anticipated volume of data, the drill string 903 will transmit data at a rate of at least 100 bits/second, and on up to at least 1,000,000 bits/second. However, signal attenuation is a concern. A typical length for a section 106 of pipe is 30″ 120″. Drill strings in oil and gas production can extend as long as 20,000″ 30,000″, or longer, which means that as many as 700 sections of drill pipe, down hole tools, collars, subs, etc. can found in a drill string such as the drill string 903. The transmission line created through the drill string by the pipe described above will typically transmit the information signal a distance of 1,000 to 2,000 feet before the signal is attenuated to the point where amplification will be desirable. Thus, the repeaters 930 are provided for approximately for some of the components in the drill string 903, for example, 5% of components not to exceed 10%, in the illustrated embodiment. In the illustrated embodiment, the repeaters 930 are housed in the nodes 1002, as will be described more fully below, although this is not necessary to the practice of the invention.

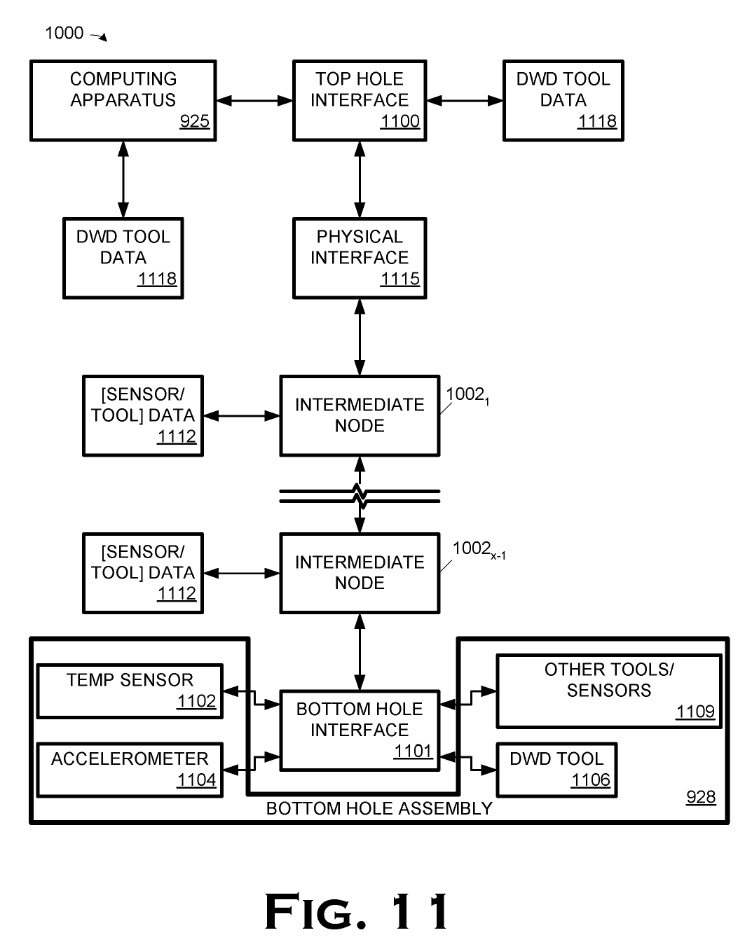

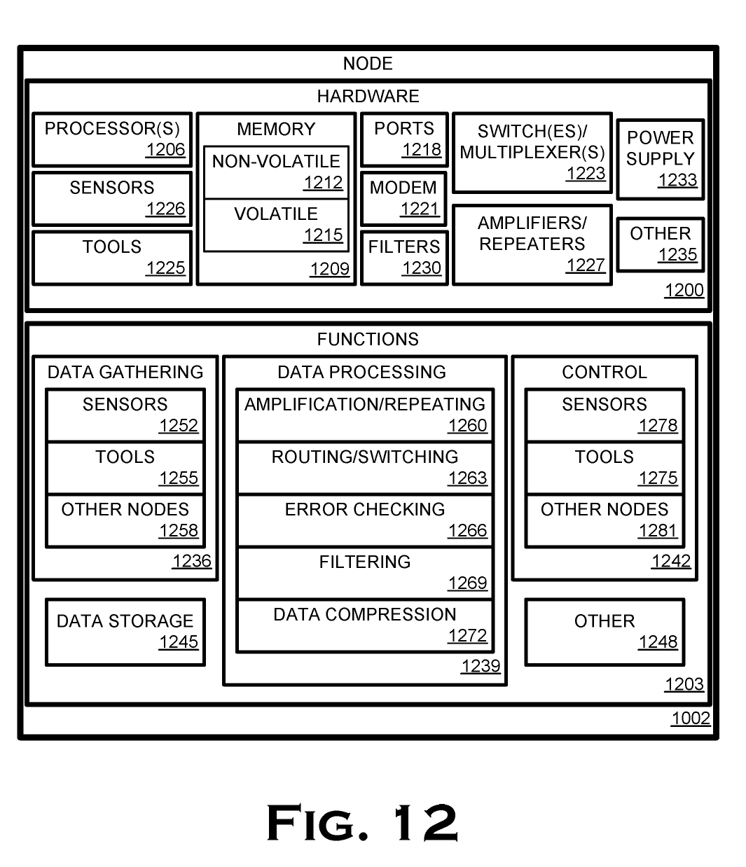

Still referring to FIG. 10, down-hole network 1000 includes a top-hole node 10020 and a bottom-hole node 1002x that implement, as shown in FIG. 11, a top-hole interface 1100 and a bottom-hole interface 1101, respectively. The bottom-hole interface 1101 may interface to various components located in or proximate a bottom-hole assembly 928. For example, a bottom-hole interface 1101 may interface with a temperature sensor 1102, an accelerometer 1104, a DWD (“diagnostic-while-drilling”) tool 1106, or other tools or sensors 1109, as needed.

The bottom-hole interface 1101 may communicate with an intermediate node 1002x-1 located up the drill string 903. The intermediate node 1002x-1 may also interface with or receive tool or sensor data 1112 for transmission up or down the network 1000. Likewise, other nodes 1002, such as a second intermediate node 10021, may be located along the drill string 903 and interface with other sensors or tools to gather data 1112 therefrom. Any number of intermediate nodes 1002 may be used along the network 1000 between the top-hole interface 1100 and the bottom-hole interface 1101.

A physical interface 1115 may be provided to connect network components to a drill string 903. For example, since data is transmitted directly up the drill string 903 on cables or other transmission media integrated directly into drill pipe or other drill string components, the physical interface 1115 provides a physical connection to the drill string so data may be routed off of the drill string 903 to network components, such as a top-hole interface 1100, or the computing apparatus 925, shown in FIG. 10. One particular implementation employs a swivel disclosed more fully in U.S. application Ser. No. 10/315,263, entitled “Signal Connection for a Downhole Tool String (Swivel)”, and filed Dec. 10, 2002, in the name of the inventors David R. Hall, et al.

For example, a top-hole interface 1100 may be operably connected to the physical interface 1115. The top-hole interface 1100 may be connected to an analysis device, such as a computing apparatus 925. The computing apparatus 925 may be used to analyze or examine data gathered from various down-hole tools or sensors, e.g., the data 1112. Likewise, DWD tool data 1118 may be saved or output from the computing apparatus 925. Likewise, in other embodiments, DWD tool data 1118 may be extracted directly from the top-hole interface 1100 for analysis.

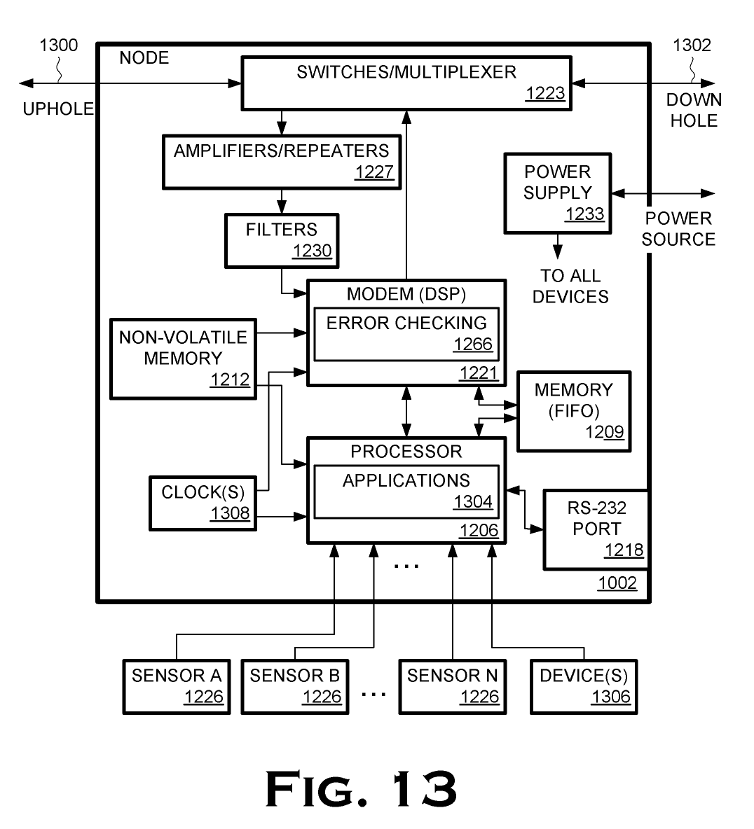

Referring to FIG. 12, a network node 1002 in accordance with the invention may include hardware 1200 providing functionality to the node 1002, as well as functions 1203 performed by the node 1002. The functions 1203 may be provided strictly by the hardware 1200, by software applications executable on the hardware 1200, or a combination thereof. For example, the hardware 1200 may include one or several processors 1206 capable of processing or executing instructions or other data. The processors 1206 may include hardware such as busses, clocks, cache, or other supporting hardware.

Likewise, the hardware 1200 may include memory 1209, both volatile memory 1212 and non-volatile memory 1215, providing data storage and staging areas for data transmitted between hardware components 1200. Volatile memory 1212 may include random access memory (“RAM”) or equivalents thereof, providing high-speed memory storage. Memory 1209 may also include selected types of non-volatile memory 1215 such as read-only-memory (“ROM”), or other long term storage devices, such as hard drives and the like. Ports 1218 such as serial, parallel, or other ports 1218 may be used to input and output signals up-hole or down-hole from the node 1002, provide interfaces with sensors or tools located proximate the node 1002, or interface with other tools or sensors located in a drilling environment.

A modem 1221 may be used to modulate digital data onto a carrier signal for transmission up-hole or down-hole along the network 1000. Likewise, the modem 1221 may demodulate digital data from signals transmitted along the network 1000. A modem 1221 may provide various built in features including but not limited to error checking, data compression, or the like. In addition, the modem 1221 may use any suitable modulation type such as QPSK, OOK, PCM, FSK, QAM, or the like. The choice of a modulation type may depend on a desired data transmission speed, as well as unique operating conditions that may exist in a down-hole environment. Likewise, the modem 1221 may be configured to operate in full duplex, half duplex, or other mode. The modem 1221 may also use any of numerous networking protocols currently available, such as collision-based protocols, such as Ethernet, or token-based protocols such as are used in token ring networks.

A node 1002 may also include one or several switches or multiplexers 1223 to filter and forward packets between nodes 1002 of the network 1000, or combine several signals for transmission over a single medium. Likewise, a demultiplexer (not shown) may be included with the multiplexer 1223 to separate multiplexed signals received on a transmission line.

A node 1002 may include various sensors 1226 located within the node 1002 or interfacing with the node 1002. Sensors 1226 may include data gathering devices such as pressure sensors, inclinometers, temperature sensors, thermocouplers, accelerometers, imaging devices, seismic devices, or the like. Sensors 1226 may be configured to gather data for transmission up the network 1000 to the grounds surface, or may also receive control signals from the surface to control selected parameters of the sensors 1226. For example, an operator at the surface may actually instruct a sensor 1226 to take a particular measurement. Likewise, other tools 1225 located down-hole may interface with a node 1002 to gather data for transmission up-hole, or follow instructions received from the surface.

Since a drill string may extend into the earth 20,000 feet or more, signal loss or signal attenuation that occurs when transmitting data along the down-hole network 1000, may be an important or critical issue. Various hardware or other devices of the down-hole network 1000 may be responsible for causing different amounts of signal attenuation. For example, since a drill string is typically comprised of multiple segments of drill pipe or other drill tools, signal loss may occur each time a signal is transmitted from one down-hole tool to another. Since a drill string may include several hundred sections of drill pipe or other tools, the total signal loss that occurs across all of the tool joints 118 may be quite significant. Moreover, a certain level of signal loss may occur in the cable or other transmission media extending from the bottom-hole assembly 928 to the surface.

To reduce data loss due to signal attenuation, amplifiers or repeaters 1272, may be spaced at various intervals along the down-hole network 1000. Amplifiers receive a data signal, amplify it, and transmit it to the next node 1002. Like an amplifier, a repeater receives a data signal and retransmits it at a higher power. However, unlike an amplifier, a repeater may remove noise from the data signal and, in some embodiments, check for and remove errors from the data stream.

Amplifiers, or “repeaters,” are provided for approximately for some of the components in the drill string 903, for example, 5% of components not to exceed 10%, in the illustrated embodiment. Although the amplifiers/repeaters 1272 are shown comprising a portion of the node 1002 in FIG. 12, such is not necessary to the practice of the invention. One suitable, stand alone repeater unit is disclosed in U.S. application Ser. No. 10/613,549, entitled “Link Module For a Downhole Drilling Network,” and filed Jul. 2, 2003, in the name of David R. Hall, et al.

Still referring to FIG. 12, a node 1002 may include various filters 1230. Filters 1230 may be used to filter out undesired noise, frequencies, and the like that may be present or introduced into a data signal traveling up or down the network 1000. Likewise, the node 1002 may include a power supply 1233 to supply power to any or all of the hardware 1200. The node 1002 may also include other hardware 1235, as needed, to provide desired functionality to the node 1002.

The node 1002 may provide various functions 1203 that are implemented by software, hardware, or a combination thereof. For example, functions 1203 of the node 1002 may include data gathering 1236, data processing 1239, control 1242, data storage 1245, and other functions 1248. Data may be gathered from sensors 1252 located down-hole, tools 1255, or other nodes 1258 in communication with a selected node 1002. This data 1236 may be transmitted or encapsulated within data packets transmitted up and down the network 1000.

Likewise, the node 1002 may provide various data processing functions 1239. For example, data processing may include data amplification or repeating 1260, routing or switching 1263 data packets transmitted along the network 1000, error checking 1266 of data packets transmitted along the network 1000, filtering 1269 of data, as well as data compression or decompression 1272. Likewise, a node 1002 may process various control signals 1242 transmitted from the surface to tools 1275, sensors 1278, or other nodes 1281 located down-hole. Likewise, a node 1002 may store data that has been gathered from tools, sensors, or other nodes 1002 within the network 1000. Likewise, the node 1002 may include other functions 1248, as needed.

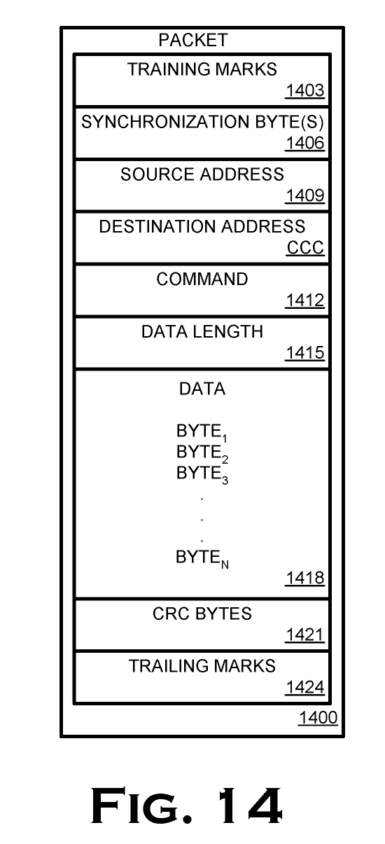

Referring to FIG. 13, in selected embodiments, a node 1002 may include various components to provide desired functionality. For example switches and/or multiplexers 1223 may be used to receive, switch, and multiplex or demultiplex signals, received from other, up-hole and/or down-hole nodes 1002 over the lines 1300, 1302, respectively. The switches/multiplexers 1223 may direct traffic such as data packets or other signals into and out of the node 1002, and may ensure that the packets or signals are transmitted at proper time intervals, frequencies, or a combination thereof.

In certain embodiments, the multiplexer 1223 may transmit several signals simultaneously on different carrier frequencies. In other embodiments, the multiplexer 1223 may coordinate the time-division multiplexing of several signals. Signals or packets received by the switch/multiplexer 1223 may be amplified by the amplifiers/repeaters 1227 and filtered by the filters 1230, such as to remove noise. In other embodiments, the signals may be received, data may be demodulated therefrom and stored, and the data may be remodulated and retransmitted on a selected carrier frequency having greater signal strength. The modem 1221 may be used to demodulate analog signals received from the switch/multiplexer into digital data and modulate digital data onto carriers for transfer to the switches/multiplexer where they may be transmitted uphole or down-hole The modem 1221 may also perform various tasks such as error-checking 1266. The modem 1221 may also communicate with a processor 1206. The processor 1206 may execute any of numerous applications 106. For example, the processor 1206 may run applications 1304 whose primary function is acquire data from one or a plurality of sensors 1226a-c. For example, the processor 1206 may interface to sensors 1226 such as inclinometers, thermocouplers, accelerometers, imaging devices, seismic data gathering devices, or other sensors. Thus, the node 1002 may include circuitry that functions as a data acquisition tool.

In other embodiments, the processor 1206 may run applications 1304 that may control various devices 1306 located down-hole. That is, not only may the node 1002 be used as a repeater, and as a data gathering device, but may also be used to receive or provide control signals to control selected devices as needed. The node 1002 may include a memory device 1209 implementing a data structure, such as a first-in, first out (“FIFO”) queue, that may be used to store data needed by or transferred between the modem 1221 and the processor 1206.

Other components of the node 1002 may include non-volatile memory 1212, which may be used to store data, such as configuration settings, node addresses, system settings, and the like. One or several clocks 1308 may be provided to provide clock signals to the modem 1221, the processor 1206, or any other device. A power supply 1233 may receive power from an external power source such as batteries. The power supply 1233 may provide power to any or all of the components located within the node 1002. Likewise, an RS232 port 1218 may be used to provide a serial connection to the node 1002.

Thus, the node 1002 described in FIG. 13 may have many more functions than those supplied by a simple signal repeater. The node 1002 may provide many of the advantages of an addressable node on a local area network. The addressable node may amplify signals received from up-hole over the line 1300 or from down-hole over the line 1302 from other sources, be used as a point of data acquisition, and be used to provide control signals to desired devices 1306. These represent only a few examples of the versatility of the node 1002. Thus, the node 1002, although useful and functional as a repeater, may have a greatly expanded capability.

In general, the node 1002 may be housed in a module (not shown) having a cylindrical or polygonal housing defining a central bore. Size limitations on the electronic components of the node 1002 may restrict the diameter of the bore to slightly smaller than the inner bore diameter of a typical section of drill pipe 106. The module is configured for insertion into a host down-hole tool and may be removed or inserted as needed to access or service components located therein. In one particular embodiment, at least some of the electronic components are mounted in sealed recesses on the external surface of the housing and channels are milled into the body of the module for routing electrical connections between the electronic components.

FIG. 14 illustrates an exemplary embodiment of a packet 1400 whose structure may be used to implement the packets 1009, 1012 in FIG. 10. The packet 1400 contains data, control signals, network protocols, and the like may be transmitted up and down the drill string. For example, in one embodiment, a packet 1400 in accordance with the invention may include training marks 1403. Training marks 1403 may include any overhead, synchronization, or other data needed to enable another node 1002 to receive a particular data packet 1400.

Likewise, a packet 1400 may include one or several synchronization bytes 1406. The synchronization byte 1406 or bytes may be used to synchronize the timing of a node 1002 receiving a packet 1400. Likewise, a packet 1400 may include a source address 1409, identifying the logical or physical address of a transmitting device, and a destination address 120, identifying the logical or physical address of a destination node 1002 on a network 1000.

A packet 1400 may also include a command byte 1412 or bytes 1412 to provide various commands to nodes 1002 within the network 1000. For example, the command bytes 1412 may include commands to set selected parameters, reset registers or other devices, read particular registers, transfer data between registers, put devices in particular modes, acquire status of devices, perform various requests, and the like.

Likewise, a packet 1400 may include data or information 1415 with respect to the length of data 1418 transmitted within the packet 1400. For example, the data length 1415 may be the number of bits or bytes of data carried within the packet 1400. The packet 1400 may then include data 1418 comprising a number of bytes. The data 1418 may include data gathered from various sensors or tools located down-hole, or may contain control data to control various tools or devices located down-hole. Likewise one or several CRC bytes 1421 may be used to perform error checking of other data or bytes within a packet 1400. Trailing marks 1424 may trail other data of a packet 1400 and provide any other overhead or synchronization needed after transmitting a packet 1400. One of ordinary skill in the art will recognize that network packets 1400 may take many forms and contain varied information. Thus, the example presented herein simply represents one contemplated embodiment in accordance with the invention, and is not intended to limit the scope of the invention.

In the embodiment of FIG. 10 FIG. 14, the processor 1206 and applications 1304, shown best in FIG. 13, implement the functionality of the testing apparatus 933 of FIG. 9. Each node 1002 of the downhole network 1000, first shown in FIG. 10, therefore implements a testing apparatus of the present invention, e.g., the testing apparatus 933 in FIG. 9. Since the downhole network 1000 includes several nodes 1002 distributed along the length of the drill string 903, the drill string 903 also includes the testing functionality of the present invention distributed along the drill string 903. Each testing apparatus hosted by a node 1002 tests the electromagnetic connectivity across the joints 927 down-hole between it and the next node 1002. In the case of the bottom-hole node 1002x, the testing apparatus tests the electromagnetic connectivity across the bottom-hole assembly 928. Each node 1002 gathers the reflected signal, conditions it, and transmits it up-hole to the computing apparatus 925.

The following patents and patent application are hereby incorporated herein by reference for all purposes as if expressly set forth verbatim herein:
U.S. application Ser. No. 09/909,469, entitled “Data Transmission System for a String of Downhole Components,” filed Jul. 18, 2001, in the name of the inventors David R. Hall, et al.
U.S. application Ser. No. 10/605,373, entitled “Load-Resistant Coaxial Transmission Line,” and filed Sep. 25, 2003, in the name of David R. Hall, et al.
U.S. application Ser. No. 10/315,263, entitled “Signal Connection for a Downhole Tool String (Swivel)”, and filed Dec. 10, 2002, in the name of the inventors David R. Hall, et al.
U.S. application Ser. No. 10/430,734, entitled “Loaded Transducer for Downhole Drilling Components,” filed May 6, 2003, in the name of the inventors David R. Hall, et al.
U.S. application Ser. No. 10/613,549, entitled “Link Module For a Downhole Drilling Network,” and filed Jul. 1, 2003, in the name of David R. Hall, et al.
U.S. Pat. No. 6,670,880, entitled “Down-hole Data Transmission System,” and issued Dec. 30, 2003, in the name of the inventors David R. Hall, et al.
U.S. Provisional Application Ser. No. 60/481,225, entitled “Downhole Network,” and filed Aug. 13, 2003, in the name of David R. Hall, et al.

This concludes the detailed description. The particular embodiments disclosed above are illustrative only, as the invention may be modified and practiced in different but equivalent manners apparent to those skilled in the art having the benefit of the teachings herein. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

1. A method of testing electromagnetic connectivity in transmission path in a drill string, comprising:
transmitting a test signal down the transmission path;
receiving a reflection of the test signal; and
determining from the reflection whether there is an interruption in the electromagnetic connectivity in the transmission path.

2. The method of claim 1, wherein transmitting the test signal includes transmitting a sine wave signal.

3. The method of claim 1, wherein transmitting the test signal includes transmitting the test signal from a test apparatus elctromagnetically coupled to the transmission path.

4. The method of claim 1, wherein transmitting the test signal includes transmitting the test signal across an electromagnectically coupled joint.

5. The method of claim 1, wherein transmitting the test signal includes transmitting the test signal across a plurality of electromagnectically coupled joints.

6. The method of claim 1, wherein receiving the reflection includes receiving a reflection indicating one of a good connection in the drill string and a bad connection in the drill string.

7. The method of claim 6, wherein receiving the reflection indicating a bad connection includes receiving a signal indicating one of a shorted box end, an open box end, a shorted pin end, and an open pen end.

8. The method of claim 1, wherein determining from the reflection whether there is an interruption in the electromagnetic connectivity in the transmission path includes determining whether the interruption occurs from a shorted box end, an open box end, a shorted pin end, and an open pen end.

9. The method of claim 1, determining from the reflection whether there is an interruption in the electromagnetic connectivity includes comparing the reflection to a reference.

10. The method of claim 9, wherein comparing the reflection to a reference includes one of visually comparing the reflection to a reference and electronically comparing the reflection to a reference.

11. The method of claim 1, further comprising generating the test signal.

12. The method of claim 1, further comprising displaying the reflection before the determination.

13. The method of claim 1, further comprising indicating whether there is an interruption in the electromagnetic connectivity in the transmission path.

14. An apparatus for testing electromagnetic connectivity in a transmission path in a drill string, comprising:
a signal generator that generates a test signal into the transmission path in the drill string;
a receiver for a reflection of the test signal; and
means for determining from the reflection whether there is an interruption in the electromagnetic connectivity in the transmission path.

15. The apparatus of claim 14, wherein the generator generates a sine waveform.

16. The apparatus of claim 14, wherein the generator comprises one of a crystal-based oscillator and a network analyzer.

17. The apparatus of claim 14, wherein at least one of the generator and the receiver includes a coil.

18. The apparatus of claim 14, wherein the generator and the receiver share a single coil.

19. The apparatus of claim 14, wherein the determining means includes a signal processor that compares the reflection to a reference.

20. The apparatus of claim 14, wherein the signal processor comprises one of an electronic amplifier and a programmed computing apparatus.

21. The apparatus of claim 14, further comprising means for indicating whether there is an interruption in the electromagnetic connectivity in the transmission path.

22. An apparatus for testing electromagnetic connectivity in a transmission path in a drill string, comprising:
a signal generator;
a coil through which a test signal generated by the signal generator may be transmitted into a drill string and through which a reflection of the test signal may be received; and
means for determining from the reflection whether there is an interruption in the electromagnetic connectivity in the transmission path.

23. The apparatus of claim 22, wherein the signal generator comprises one of a crystal-based oscillator and a network analyzer.

24. The apparatus of claim 22, wherein the determining means includes a signal processor that compares the reflection to a reference.

25. The apparatus of claim 22, wherein the signal processor comprises one of an electronic amplifier and a programmed computing apparatus.

26. The apparatus of claim 22, further comprising an indicator capable of indicating whether there is an interruption in the electromagnetic connectivity in the transmission path.

27. The apparatus of claim 22, wherein the indictor is capable of at least one of visually and aurally indicating whether there is an interruption in the electromagnetic connectivity in the transmission path.

28. An apparatus, comprising:
a drill string;
a transmission path through the drill string;
a testing apparatus electromagnetically coupled to the transmission path and capable of:
transmitting a test signal down at least a portion of the transmission path;
receiving a reflection of the test signal; and
determining from the reflection whether there is an interruption in the electromagnetic connectivity in the transmission path.

29. The apparatus of claim 28, wherein the drill string includes at least one of a section of drill pipe, a tool, and a bit.

30. The apparatus of claim 28, wherein the transmission path includes:
a first pair of electromagnetic couplers;
a first conductor electrically connecting the first pair of electromagnetic couplers;
a second conductor; and
a second pair of electromagnetic couplers connected by the second conductor, one of the second pair of electromagnetic couplers being electromagnectically coupled to one of the first pair of electromagnetic couplers.

31. The apparatus of claim 28, wherein the testing apparatus comprises a dedicated section of the drill string.

32. The apparatus of claim 28, wherein the testing apparatus is hosted on a non-dedicated section of pipe.

33. The apparatus of claim 28, wherein the testing apparatus comprises:
for a signal generator that generates a test signal into the drill string;
a receiver that receives a reflection of the test signal; and
means for determining from the reflection whether there is an interruption in the electromagnetic connectivity in the transmission path.

34. The apparatus of claim 28, wherein the testing apparatus comprises:
a signal generator;
a coil through which a test signal generated by the signal generator may be transmitted into a drill string and through which a reflection of the test signal may be received; and
means for determining from the reflection whether there is an interruption in the electromagnetic connectivity in the transmission path.

35. The apparatus of claim 28, further comprising a downhole local area network over which the testing apparatus can transmit the data representing the reflection to the test signal.

36. An apparatus for testing electromagnetic connectivity in transmission path in a drill string, comprising:
a drill string;
a transmission path through the drill string;
at least one testing apparatus capable of:
transmitting a test signal down at least a portion of the transmission path; and
receiving a reflection of the test signal; and
transmitting data representing the reflection;
a downhole local area network over which the testing apparatus can transmit the data representing the reflection to the surface; and
a computing apparatus programmed to receive the transmitted data and facilitate determining from the reflection whether there is an interruption in the electromagnetic connectivity in the transmission path.

37. The apparatus of claim 36, wherein the drill string includes at least one of a section of drill pipe, a tool, and a bit.

38. The apparatus of claim 36, wherein the transmission path includes:
a first pair of electromagnetic couplers;
a first conductor electrically connecting the first pair of electromagnetic couplers;
a second conductor; and
a second pair of electromagnetic couplers connected by the second conductor, one of the second pair of electromagnetic couplers being electromagnectically coupled to one of the first pair of electromagnetic couplers.

39. The apparatus of claim 36, wherein the testing apparatus comprises a dedicated section of the drill string.

40. The apparatus of claim 36, wherein the testing apparatus is hosted on a non-dedicated section of pipe.

41. The apparatus of claim 36, wherein the testing apparatus comprises:
means for generating a test signal;
means for transmitting the test signal into a drill string;
means for receiving a reflection of the test signal may be received; and
means for determining from the reflection whether there is an interruption in the electromagnetic connectivity in the transmission path.

42. The apparatus of claim 36, wherein the testing apparatus comprises:
a signal generator;
a coil through which a test signal generated by the signal generator may be transmitted into a drill string and through which a reflection of the test signal may be received; and
means for determining from the reflection whether there is an interruption in the electromagnetic connectivity in the transmission path.
